(19) United States
(12) Patent Application Publication
(10) Pub. No.: US 2010/0140747 A1
(43) Pub. Date: Jun. 10, 2010

(54) Semiconductor devices

(75) Inventors: Seung-Man Choi, Hwaseong-si (KR); Soon-Sik Hwang, Bucheon-si (KR); Ki-Chul Park, Suwon-si (KR); Gi-Bum Kim, Yongin-si (KR); Ki-Su Kim, Seoul (KR); Sang-Chul Lee, Hwaseong-si (KR); Bae-Kyoung Kim, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/592,924

(22) Filed: Dec. 4, 2009

(30) Foreign Application Priority Data
Dec. 5, 2008 (KR) 10-2008-0123108

(51) Int. Cl. H01L 23/58; H01L 23/522; H01L 21/768

(52) U.S. Cl. 257/620; 257/773; 438/618; 257/E23.194; 257/E23.142; 257/E21.575

(57) ABSTRACT

In a method of manufacturing a semiconductor device, a pad including at least one insulating interlayer and at least one conductive wiring may be formed in a pad area of a substrate. At least one wiring may be formed adjacent to the conductive wiring. At least one insulation layer may be formed adjacent to the insulating interlayer. At least one crack preventing structure may be formed in the insulation layer. The crack preventing structure may continuously extend in the insulation layer and portions of the insulation layer may also be continuous. When a semiconductor device includes at least one crack preventing structure disposed adjacent to a pad, a degradation of the semiconductor chip caused by an external impact and/or a stress may be efficiently prevented by the crack preventing structure.

### CROSS-REFERENCE TO RELATED APPLICATION

This application claims priority under 35 U.S.C. §119 to Korean patent Application No. 2008-123108, filed in the Korean Intellectual Property Office on Dec. 5, 2008, the contents of which are hereby incorporated by reference herein in their entirety.

### BACKGROUND

1. Technical Field

Exemplary embodiments of the inventive concept relate to semiconductor devices and methods of manufacturing semiconductor devices. More particularly, exemplary embodiments of the inventive concept relate to semiconductor devices having crack preventing structures and method of manufacturing the semiconductor devices having the crack preventing structures.

2. Description of the Related Art

As semiconductor devices have been highly integrated, the sizes of unit cells in the semiconductor devices have been rapidly reduced. Although the sizes of the unit cells are considerably decreased, the unit cell may ensure desired physical properties and electrical characteristics, and also the unit cells may meet improved physical properties and electrical characteristics. However, the semiconductor device may not properly absorb external physical and/or electrical impacts when the unit cells have minute sizes, so that the semiconductor device may be easily damaged by the external impacts.

Current semiconductor devices include multi-layered metal wirings of copper (Cu) and insulating interlayers of low-k material to reduce the RC delay of the semiconductor devices. After a semiconductor wafer having electrical structures is divided into semiconductor chips, the semiconductor chips are subjected to a packaging process. When the semiconductor chips are obtained by cutting the semiconductor wafer, many physical impacts may be applied to an edge portion of the semiconductor chip. If the applied impacts are not properly dissipated or absorbed, cracks may be generated between the metal wiring and the insulating interlayer, or the insulating interlayer may be lifted from a semiconductor substrate or the metal wiring. Particularly, the cracks may be easily generated between the metal wiring and the insulating interlayer or the insulating interlayer may be more easily lifted from the substrate when the metal wiring includes copper and the insulating interlayer includes the low-k material.

FIG. 1 is an electron microscopic image showing a conventional semiconductor chip having a failure caused by the cracks or the lifting of the insulating interlayer.

As shown in FIG. 1, the cracks or the lifting of the insulating interlayer are frequently generated at the edge portion of the semiconductor device while dicing the semiconductor wafer using a diamond wheel or a laser. The cracks or the lifting of the insulating interlayer may disturb an electrical connection between the semiconductor chip and an external device, so that the semiconductor device may provide poor electrical connection relative to the external device, and particles may easily permeate into the cracks or the lifted insulation interlayer to degrade the reliability of the semiconductor device.

To solve the above-described drawbacks, a crack stopper has been employed in a semiconductor device.

FIG. 2 is an electron microscopic image showing one conventional semiconductor device including a crack stopper having a line structure.

Referring to FIG. 2, the crack stopper is usually formed at an edge portion of the semiconductor device as a structure including several lines so as to prevent cracks from forming in the semiconductor device.

FIG. 3 is a schematic plan view showing another conventional semiconductor device including a crack stopper having a bar structure, and FIG. 4 is a schematic perspective view showing the conventional semiconductor device in FIG. 3.

Referring to FIGS. 3 and 4, the conventional semiconductor device includes a metal wiring 15 formed on a substrate 10, an etch stop layer 20 covering the metal wiring 15, an insulating interlayer 25 formed on the etch stop layer 20, and a crack stopper (not illustrated) provided in the insulating interlayer 25. The crack stopper is usually positioned in a trench 30 formed in the insulating interlayer 25. Because the crack stopper is located in the trench 30 having a net structure, adjacent portions of the insulating interlayer 25 are separated from each other by the crack stopper.

FIG. 5 is an electron microscopic image showing a conventional semiconductor device having a failure generated in a crack stopper.

As illustrated in FIG. 5, a portion 26 of an insulating interlayer is lifted from a metal wiring by the stress concentrated at the portion 26 of the insulating interlayer, although portions of the insulating interlayer are separated by a crack stopper 31. When the crack stopper 31 has an asymmetric or irregular structure, the stress may not be uniformly distributed in the insulating interlayer, so that the stress may be concentrated at a predetermined portion of the insulating interlayer. As a result, the stressed portion of the insulating interlayer may be lifted from the metal wiring to degrade electrical and/or physical characteristics of the semiconductor device.

### SUMMARY

Exemplary embodiments provide a semiconductor device including a crack preventing structure continuously extending in an insulation layer in a pad area of the semiconductor device.

Exemplary embodiments provide a method of manufacturing a semiconductor device including a crack preventing structure continuously extending in an insulation layer in a pad area of the semiconductor device.

According to one aspect of exemplary embodiments, there is provided a semiconductor device including a wiring formed in a pad area of a substrate, an insulation layer formed on the wiring, and a crack preventing structure formed through the insulation layer. The crack preventing structure may include portions continuously extending in the insulation layer such that adjacent portions of the insulation layer may be continuous with respect to each other.

In exemplary embodiments, an etch stop layer may be formed between the wiring and the insulation layer. The crack preventing structure may pass through the etch stop layer to make contact with the wiring.

In exemplary embodiments, the crack preventing structure may have a zigzag shape, a spiral shape or a helical matrix shape.

In exemplary embodiments, the crack preventing structure may include a conductive material substantially the same as or substantially similar to that of the wiring. For example, the crack preventing structure may include metal and/or metal compound.

In exemplary embodiments, the wiring may include copper and the insulation layer may include silicon oxide or oxide containing carbon.

In exemplary embodiments, the insulation layer may have a trench where the crack preventing structure may be positioned.

According to another aspect of exemplary embodiments, there is provided a semiconductor device including unit cells formed in a cell area of a substrate; circuit elements formed in a peripheral circuit area of the substrate, a plurality of wirings formed in a pad area of the substrate, a plurality of insulation layers formed on the plurality of wirings, respectively, and a plurality of crack preventing structures between each wiring and each insulation layer. The crack preventing structures continuously extend in the insulation layers such that adjacent portions of the insulation layers are continuous.

In exemplary embodiments, a pad may be formed adjacent to the crack preventing structures. The pad may include a plurality of conductive wirings and a plurality of insulating interlayers interposed between adjacent conductive wirings.

In exemplary embodiments, a passivation layer covering the pad and an upper most crack preventing structure may be provided. The passivation layer may have an opening that partially exposes an upper most conductive wiring of the pad.

In exemplary embodiments, the semiconductor device may include a first wiring formed on the pad area, a first insulation layer formed on the first wiring, a first crack preventing structure formed through the first insulation layer, a second wiring formed on the first crack preventing structure and the first insulation layer, a second insulation layer formed on the second wiring, a second crack preventing structure formed through the second insulation layer, a third wiring formed on the second crack preventing structure and the second insulation layer, a third insulation layer formed on the third wiring; and a third crack preventing structure formed through the third insulation layer. The first crack preventing structure may make contact with the first wiring and the second crack preventing structure may make contact with the second wiring. Additionally, the third crack preventing structure may make contact with the third wiring.

In exemplary embodiments, each of the first to the third crack preventing structures may have a zigzag shape, a spiral shape or a helical matrix shape.

According to another aspect of exemplary embodiments, there is provided a method of manufacturing a semiconductor device. In the method of manufacturing a semiconductor device, a pad including at least one insulating interlayer and at least one conductive wiring is formed in a pad area of a substrate. At least one wiring is formed adjacent to the conductive wiring. At least one insulation layer is formed adjacent to the insulating interlayer. At least one crack preventing structure is formed in the insulation layer. The crack preventing structure may continuously extend in the insulation layer, and portions of the insulation layer are continuous with respect to each other.

In exemplary embodiments, the crack preventing structure may be formed in a trench formed by partially etching the insulation layer. The insulating interlayer and the insulation layer may be simultaneously formed.

In exemplary embodiments, the conductive wiring may be formed together with the wiring and the crack preventing structure.

In exemplary embodiments, the method further includes: forming a first conductive wiring on the pad area; forming a first wiring adjacent to the first conductive wiring; forming a first insulating interlayer covering the first conductive wiring; forming a first insulation layer covering the first wiring; forming a second conductive wiring through the first insulating interlayer; forming a first crack preventing structure through the first insulation layer, the first crack preventing structure making contact with the first wiring; forming a second insulating interlayer on the first insulating interlayer; forming a second insulation layer on the first insulation layer; forming a third conductive wiring through the second insulating interlayer; forming a second wiring on the first crack preventing structure and the first insulation layer; forming a third insulating interlayer on the second insulating interlayer; forming a third insulation layer on the second wiring; forming a fourth conductive wiring through the third insulating interlayer; and forming a second crack preventing structure through the third insulation layer, the second crack preventing structure making contact with the second wiring.

In exemplary embodiments, the method further includes: forming a fourth insulating interlayer on the third insulating interlayer; forming a fourth insulation layer on the second crack preventing structure and the third insulation layer; forming a fifth conductive wiring through the fourth insulating interlayer; and forming a third wiring on the second crack preventing structure and the fourth insulation layer.

In exemplary embodiments, the wiring may be formed using copper and the insulation layer may be formed using silicon oxide or oxide containing carbon. Further, the crack preventing structure may be formed using metal and/or metal oxide.

According to exemplary embodiments, a semiconductor device may include at least one crack preventing structure disposed adjacent to a pad, so that a degradation of the semiconductor device caused by an external impact and/or a stress may be efficiently prevented by the crack preventing structure. Since the crack preventing structure having various constructions may be formed together with the pad of the semiconductor device, the crack preventing structure may be obtained by simplified processes without additional processes for the crack preventing structure. The various crack preventing structures may be properly employed in various semiconductor devices, for example, DRAM devices, SRAM devices, flash memory devices, PRAM devices, etc.

### BRIEF DESCRIPTION OF THE DRAWINGS

The foregoing and other features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is an electron microscopic image showing a conventional semiconductor chip having a failure caused by cracks and a lifting of an insulating interlayer.

FIG. 2 is an electron microscopic image showing one conventional semiconductor device including a crack stopper having a line structure.

FIG. 3 is a schematic plan view showing another conventional semiconductor device including a crack stopper having a bar structure.

FIG. 4 is a schematic perspective view showing the conventional semiconductor device in FIG. 3.

FIG. 5 is an electron microscopic image showing a conventional semiconductor device having a failure generated in a crack stopper.

FIG. 6 is a schematic plan view illustrating a semiconductor device having a crack preventing structure in accordance with exemplary embodiments.

FIG. 7 is a schematic perspective view illustrating the semiconductor device having the crack preventing structure in FIG. 6.

FIG. 8 is a schematic cross-sectional view illustrating a semiconductor device having a crack preventing structure in accordance with exemplary embodiments.

FIG. 9 is a schematic cross-sectional view illustrating a semiconductor device having a crack preventing structure in accordance with exemplary embodiments.

FIG. 10 is a schematic cross-sectional view illustrating a semiconductor device in accordance with exemplary embodiments.

FIG. 11 is a schematic plan view illustrating a semiconductor chip in accordance with exemplary embodiments.

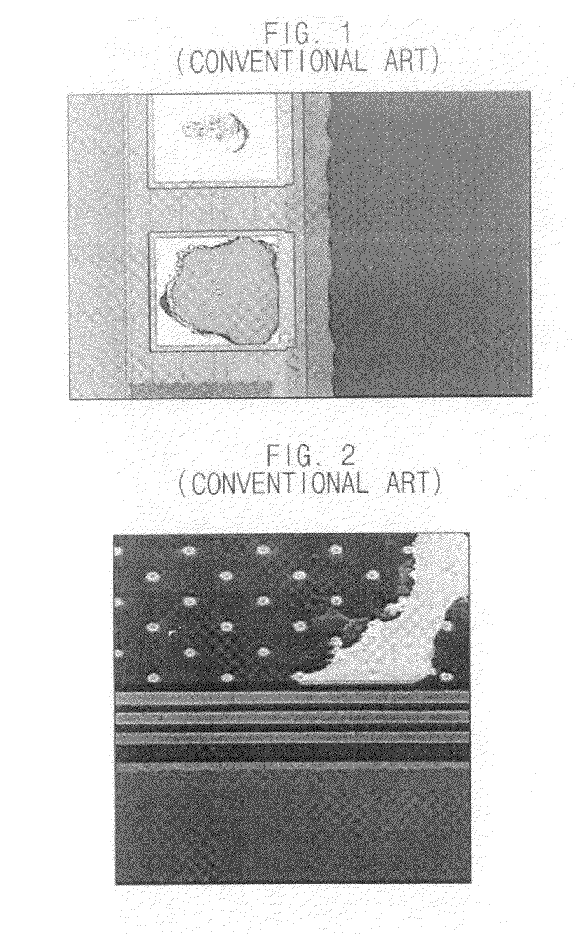

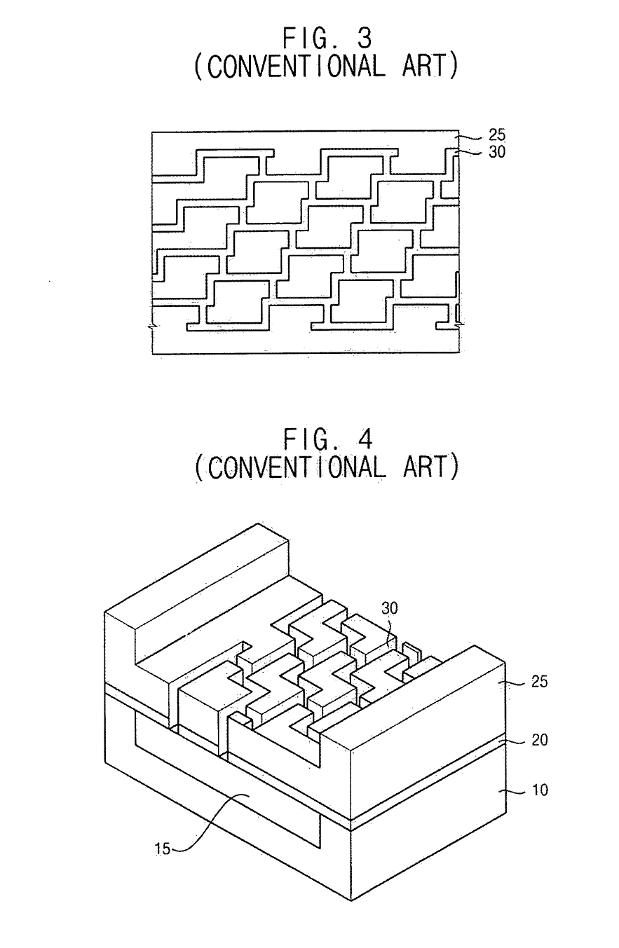

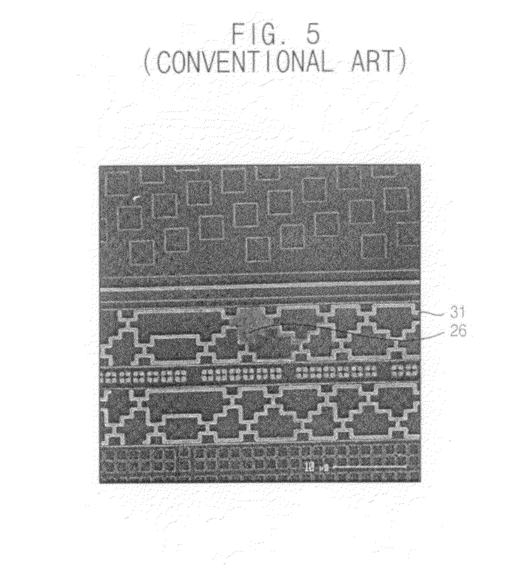

### DESCRIPTION OF EMBODIMENTS

Exemplary embodiments of the inventive concept are described more fully hereinafter with reference to the accompanying drawings. The inventive concept may, however, be embodied in many different forms and should not be construed as limited to the exemplary embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like or similar reference numerals refer to like or similar elements throughout. As used herein, the term “and/or” includes any and all combinations of one or more of the associated listed items.

It will be understood that, although the terms first, second, third etc. may be used herein to describe various elements, components, regions, layers, patterns and/or sections, these elements, components, regions, layers, patterns and/or sections should not be limited by these terms. These terms are only used to distinguish one element, component, region, layer pattern or section from another region, layer, pattern or section. Thus, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For exemplary, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of illustratively idealized exemplary embodiments (and intermediate structures) of the inventive concept. As such, variations from the shapes of the illustrations as a result, for exemplary, of manufacturing techniques and/or tolerances, are to be expected. Thus, exemplary embodiments should not be construed as limited to the particular shapes of regions illustrated herein but are to include deviations in shapes that result, for exemplary, from manufacturing. For exemplary, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

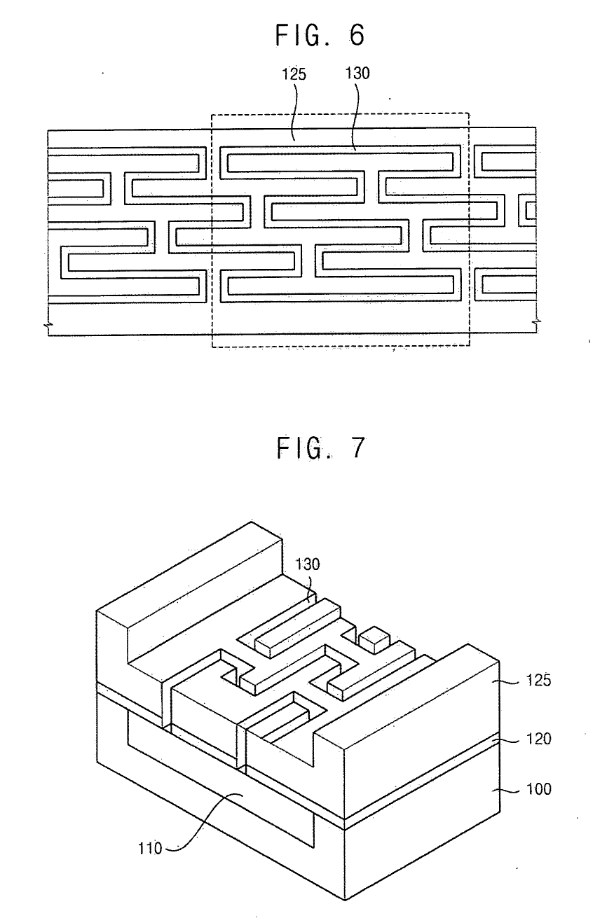

FIG. 6 is a schematic plan view illustrating a semiconductor device having a crack preventing structure in accordance with exemplary embodiments. FIG. 7 is a schematic perspective view illustrating the semiconductor device having the crack preventing structure in FIG. 6. In FIGS. 6 and 7, the crack preventing structure may have a continuous structure. That is, portions of the crack preventing structure may not be separated from one another in an insulation layer. For example, the crack preventing structure may extend in a maze shape.

Referring to FIGS. 6 and 7, the semiconductor device includes a substrate 100, a wiring 110, an etch stop layer 120, an insulation layer 125 and a crack preventing structure 135 for preventing cracks from being generated in the insulation layer 125 or between the wiring 110 and the insulation layer 125. Further, the crack preventing structure 135 may prevent a lifting of the insulation layer 125 from underlying structures including the wiring 110.

In exemplary embodiments, the semiconductor device may include a cell area, a peripheral circuit area and a pad area. A plurality of memory cells or unit cells in the semiconductor device may be positioned in the cell area, and logic elements or circuit elements may be located in the peripheral circuit area. Further, a plurality of pads may be provided in the pad area for electrical connections between the semiconductor device and other devices. For example, the pad area may be located at an edge portion of the semiconductor device so as to surround the cell and the peripheral circuit areas. Electrical signals may be applied to the semiconductor device through the pads.

The substrate 100 may generally include a semiconductor substrate, a substrate including a semiconductor layer, or a metal oxide substrate. For example, the substrate 100 may include a silicon (Si) substrate, a germanium (Ga) substrate, a silicon-on-insulator (SOI) substrate, a germanium-on-insulator (GOI) substrate, an aluminum oxide (AlOx) substrate, a titanium oxide (TiOx) substrate, etc.

The wiring 110 may include a conductive material such as metal and/or metal compound. For example, the wiring 110 may include tungsten (W), titanium (Ti), aluminum (Al), tantalum (Ta), copper (Cu), tungsten nitride (WNx), titanium nitride (TiNx), aluminum nitride (AlNx), tantalum nitride (TaNx), tungsten silicide (WSix), titanium silicide (TiSix), cobalt silicide (CoSix), nickel silicide (NiNx), etc. These may be used alone or in a mixture thereof. The wiring 110 may be obtained by a sputtering process, a chemical vapor deposition (CVD) process, an atomic layer deposition (ALD) process, a pulsed laser deposition (PLD) process, an evaporation process, etc. The wiring 110 may be buried at an upper portion of the substrate 100.

The etch stop layer 120 is positioned on the substrate 100 and the wiring 110. The etch stop layer 120 may include a material having an etching selectivity relative to the substrate 100, the wiring 110 and the insulation layer 125. For example, the etch stop layer 120 may include nitride such as silicon nitride (SiNx), or oxynitride like silicon oxynitride (SiOxNy). The etch stop layer 120 may be formed by a CVD process, a plasma enhanced chemical vapor deposition (PECVD) process, an ALD process, etc.

The insulation layer 125 is disposed on the etch stop layer 120. The insulation layer 125 may include oxide. For example, the insulation layer 125 may include undoped silicate glass (USG), spin on glass (SOG), Tonen silazene (TOSZ), flowable oxide (FOX), tetraethyl orthosilicate (TEOS), plasma enhanced-TEOS (PE-TEOS), boro-phosphor silicate glass (BPSG), high density plasma-chemical vapor deposition (HDP-CVD) oxide, etc. In an example embodiment, the insulation layer 125 may have a multi layer structure including at least two oxide films. The insulation layer 125 may be formed by a CVD process, an HDP-CVD process, an ALD process, a spin coating process, a PECVD process, etc.

In exemplary embodiments, the substrate 100 may also be divided into a cell area, a peripheral circuit area and a pad area. The memory cells or the unit cells may be provided in the cell area of the substrate 100, and the logic elements or the circuit elements may be positioned in the peripheral circuit area of the substrate 100. Further, several pads may be formed in the pad area of the substrate 100 for electrical connections between the semiconductor device and external devices or other semiconductor devices. The pad area may be located at a peripheral portion of the substrate 100.

The crack preventing structure 135 is positioned in a trench structure 130 formed through the insulation layer 125. Additionally, the crack preventing structure 135 is located in the pad area of the substrate 100. The crack preventing structure 135 may have a structure in accordance with that of the trench 130 formed through the insulation layer 125 and the etch stop layer 120, such that the underlying wiring 110 may be partially exposed through the trench 130. The trench 130 may be obtained by partially etching the insulation layer 125 and the etch stop layer 120. Since the crack preventing structure 135 is provided in the trench 130, the crack preventing structure 135 makes contact with the wiring 110.

The crack preventing structure 135 may include metal and/or metal compound. For example, the crack preventing structure 135 may be formed using tungsten, titanium, aluminum, tantalum, copper, tungsten nitride, titanium nitride, aluminum nitride, tantalum nitride, tungsten silicide, titanium silicide, cobalt silicide, nickel silicide, etc. These may be used alone or in a mixture thereof. The crack preventing structure 135 may include a material substantially the same as or substantially similar to that of the wiring 110. Alternatively, the crack preventing structure 135 may include a material different from that of the wiring 110. The crack preventing structure 135 may be formed by a sputtering process, a CVD process, an ALD process, a PLD process, an evaporation process, etc.

In exemplary embodiments, the crack preventing structure 135 may include portions bent along substantially right directions relative to one another. As for a configuration of the crack preventing structure 135, a first portion may extend in a first direction, and a second portion may extend in a second direction substantially perpendicular to the first direction. Additionally, a third portion may be prolonged along a third direction substantially perpendicular to the second direction and substantially reverse to the first direction. Furthermore, a fourth portion may extend in a fourth direction substantially perpendicular to the third direction and substantially parallel to the second direction. For example, a whole configuration of the crack preventing structure 135 may have a zigzag structure in which the crack preventing structure 135 having a line shape extending in a zigzag shape through the insulation layer 125. Thus, adjacent portions of the insulation layer 125 may not be separated from each other by the crack preventing structure 135. That is, portions of the insulation layer 125 may be continuous after the crack preventing structure 135 is provided in the insulation layer 125. As a result, the insulation layer 125 may not be lifted form the underlying structure by the crack preventing structure 135. Further, the generation of the cracks between the wiring 110 and the insulation layer 125 may be effectively prevented because of the continuously extending crack preventing structure 135. In exemplary embodiments, more than two portions of the crack preventing structure 135 may exist when the crack preventing structure 135 is cut along an arbitrary cross-section thereof.

In some exemplary embodiments, a plurality of crack preventing structures may be provided in the pad area of the substrate 100. Here, a plurality of wirings and a plurality of insulation layers may be positioned among the plurality of crack preventing structures. That is, a first wiring may be located under a first crack preventing structure formed through a first insulation layer, and a second wiring may be positioned on the first crack preventing structure. The second wiring may be formed under a second crack preventing structure formed through a second insulation layer. Additionally, a third wiring may be located on the second crack preventing structure, and a third crack preventing structure formed in a third insulation layer may be provided on the third wiring. In such a manner, the crack preventing structures, the insulation layers and the wirings may be alternatively stacked in the pad area of the substrate 100.

The crack preventing structure 135 may effectively absorb and uniformly distribute external impacts or stress applied to the substrate 100 while performing a dicing process about the substrate 100. That is, the impacts or the stress may be uniformly dissipated into the insulation layer 125 and the wiring 110 along the crack preventing structure 135 when the substrate 100 is cut using a diamond wheel or a laser. Because the crack preventing structure 135 having the substantial zigzag structure, the impacts or the stress may be effectively absorbed or dissipated by the crack preventing structure 135. Further, the crack preventing structure 135 having the zigzag structure may an improved endurance with respect to a stress applied along a direction substantially in parallel to the substrate 100.

In exemplary embodiments, portions of the insulation layer 125 may not be separated by the crack preventing structure 135. That is, the portions of the insulation layer 125 may be connected when the crack preventing structure 135 having a labyrinth structure is provided through the insulation layer 125.

Since the insulation layer 125 may have a continuous structure after forming the crack preventing structure 135, the stress or the impact may be efficiently dissipated or absorbed into the insulation layer 125, thereby preventing the lifting of the insulation layer 125 relative to the substrate 100 and/or the wiring 110.

FIG. 8 is a cross-sectional view illustrating a semiconductor device having a crack preventing structure in accordance with exemplary embodiments.

Referring to FIG. 8, the semiconductor device includes a crack preventing structure 230 embedded in an insulation layer 225. The crack preventing structure 230 may fill up a trench formed through the insulation layer 225. The trench may be formed through the insulation layer 225 by partially etching the insulation layer 225. The crack preventing structure 230 may have a shape substantially the same as that of the trench. For example, the crack preventing structure 230 may have a spiral shape. The crack preventing structure 230 may be continuously disposed in the insulation layer 225, so that portions of the insulation layer 235 may not be separated by the crack preventing structure 230. Hence, a stress may be uniformly dispersed in the insulation layer 225, and the insulation layer 225 may not be lifted from an underlying structure having a wiring. Additionally, the crack preventing structure 230 may effectively prevent a crack from being generated in the insulation layer 225.

In exemplary embodiments, a plurality of helical crack preventing structures may be provided through the insulation layer 225 to more efficiently dissipate or absorb the stress or an external impact applied to the semiconductor device. Here, the plurality of the crack preventing structures may be arranged in series. Further, a plurality of crack preventing structures having spiral shapes may be disposed in a plurality of insulation layers, respectively. Alternatively, a plurality of crack preventing structures may be stacked up in one insulation layer or a plurality of insulation layers.

When the crack preventing structure 230 has the helical shape, the stress may be transferred or dissipated in the insulation layer 225 and the external impact may be absorbed by the crack preventing structure 230. Further, a lateral stress relative to the semiconductor device may be effectively dissipated when the semiconductor device has the plurality of crack preventing structures.

The crack preventing structure 230 may include a conductive material substantially the same or substantially different from that of the wiring located beneath the insulation layer 225. Alternatively, the conductive material in the crack preventing structure 230 may be different from that of the wiring.

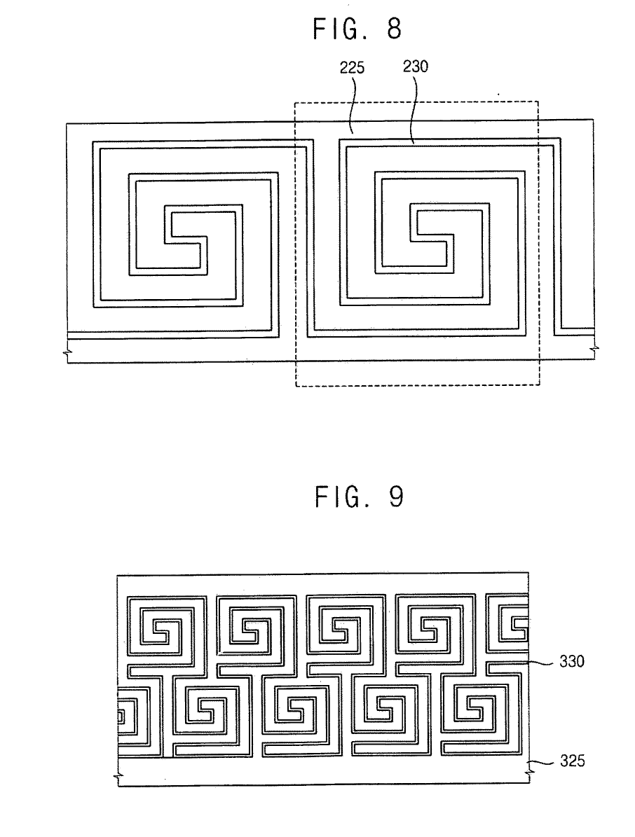

FIG. 9 is a cross-sectional view illustrating a semiconductor device having a crack preventing structure in accordance with exemplary embodiments.

Referring to FIG. 9, the semiconductor device has a crack preventing structure 330 positioned in an insulation layer 325. The crack preventing structure 330 may have helical shapes regularly arranged in a matrix shape. Portions of the crack preventing structure 330 may continuously extend in the insulation layer 325. The crack preventing structure 330 may include metal and/or metal compound. Here, a wiring of the semiconductor device may include copper, and the insulation layer 325 may include silicon oxide or oxide containing carbon.

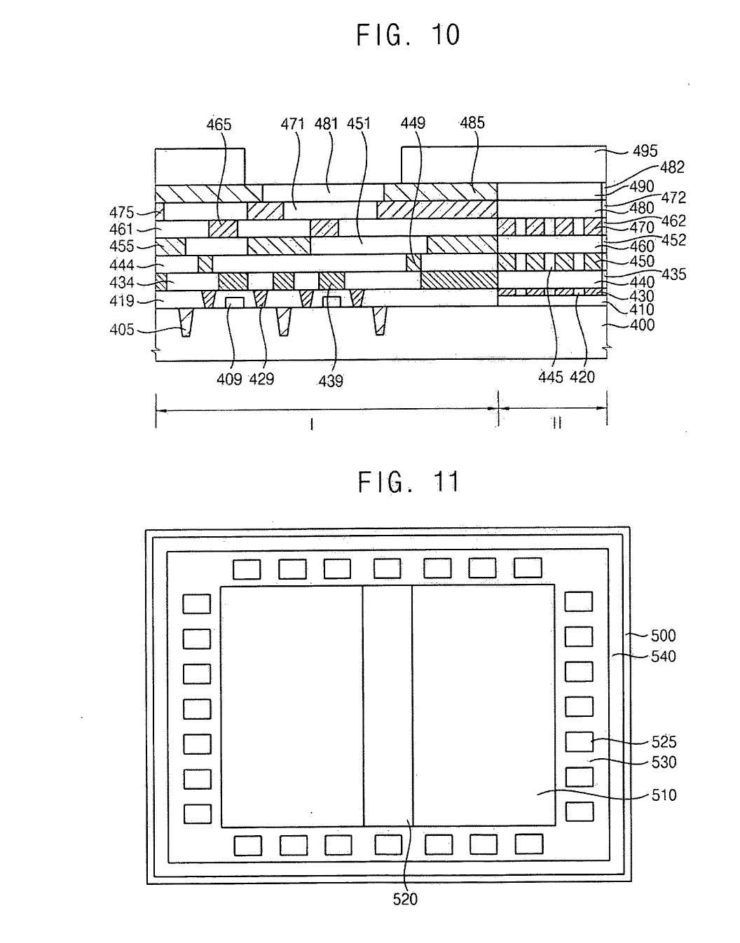

FIG. 10 is a cross-sectional view illustrating a semiconductor device having a crack preventing structure in accordance with exemplary embodiments. In FIG. 10, the semiconductor device may include a crack preventing structure having a configuration substantially the same as or substantially similar to that of the crack preventing structure described with reference to FIG. 6, FIG. 8 or FIG. 9.

Referring to FIG. 10, isolation layer patterns 405 are formed on a substrate 400 having a first area and a second area. Unit cells and circuit elements of the semiconductor devices may be formed in the first area of the substrate 400, and wirings and crack preventing structures may be provided in the second area of the substrate 400. For example, the first area of the substrate 400 may include a cell area and a peripheral circuit area, and the second area of the substrate 400 may include a pad area. The second area of the substrate 400 is divided into a first region I and a second region II. A plurality of wirings may be positioned in the first region I and a plurality of crack preventing structures may be formed in the second region II.

The substrate 400 may include a semiconductor substrate, an SOI substrate, a GOI substrate, a metal oxide substrate, etc. The isolation layer patterns 405 are positioned in the first region I of the substrate 400. The isolation layer patterns 405 may be formed on the substrate 400 using oxide by an isolation process such as a shallow trench isolation (STI) process. For example, each of the isolation layer patterns 405 may include USG, SOG, FOX, TOSZ, BPSG, PSG, TEOS, HDP-CVD oxide, etc.

In exemplary embodiments, a crack preventing structure may be employed in various semiconductor devices having a pad, for example, a dynamic random access memory (DRAM) device, a static random access memory (SRAM) device, a flash memory device, a phase change random access memory (PRAM) device, etc. The crack preventing structure may be advantageously employed in a semiconductor device having a wiring of copper and an insulation layer of a low-k material in a pad area, thereby improving the RC delay characteristics of the semiconductor device.

After forming unit cells (not illustrated) and circuit elements (not illustrated) in the first area of the substrate 400, a first conductive wiring 409 and a first wiring 410 are formed in the second area of the substrate 400. Here, the first conductive wiring 409 is positioned in the first region I and the first wiring 410 is located in the second region II. Each of the first conductive wiring 409 and the first wiring 410 may be formed using metal and/or metal compound. For exemplary, the first conductive wiring 409 and the first wiring 410 may include copper, titanium, tungsten, tantalum, aluminum, platinum, tungsten nitride, aluminum nitride, titanium nitride, tantalum nitride, nickel silicide, tungsten silicide, cobalt silicide, titanium silicide, etc. These may be used alone or in a mixture thereof. The first wiring 410 may be formed using a conductive material substantially the same as or substantially similar to that of the first conductive wiring 409. Alternatively, the first conductive wiring 409 may include a material different from that of the first wiring 410.

In exemplary embodiments, a first conductive layer (not illustrated) may be formed on the substrate 400, and then the first conductive layer may be patterned to form the first conductive wiring 409 and the first wiring 410 on the substrate 400. The first conductive layer may be formed by a sputtering process, a CVD process, an ALD process, a PLD process, an evaporation process, etc.

A first insulating interlayer 419 and a first insulation layer 420 are formed on the substrate 400. The first insulating interlayer 419 covers the first conductive wirings 409 in the first region I, and the first insulation layer 420 covers the first wiring 410 in the second region II. Here, the first conductive wiring 409 may be buried in the first insulating interlayer 419. The first insulating interlayer 419 and the first insulation layer 420 may be formed using oxide, for example, USG, SOG, TEOS, PE-TEOS, FOX, FSG, BPSG, PSG, HDP-CVD oxide, etc. The first insulating interlayer 419 and the first insulation layer 420 may be simultaneously formed on the substrate 400. Each of the first insulating interlayer 419 and the first insulation layer 420 may be formed by a CVD process, a spin coating process, a PECVD process, an HDP-CVD process, etc. Further, the first insulating interlayer 419 and the first insulation layer 420 may have level upper surfaces by a planarization process, for example, a chemical mechanical polishing (CMP) process. In an exemplary embodiment, the first insulating interlayer 419 may have a thickness substantially larger than that of the first insulation layer 420 when the first wiring 410 has a height substantially smaller than that of the first conductive wiring 409.

A first hole (not illustrated) is formed through the first insulating interlayer 419 by partially etching the first insulating interlayer 419. Additionally, a first trench (not illustrated) is formed through the first insulation layer 420 by partially etching the first insulation layer 410. The first hole and the first trench partially expose the first conductive wiring 409 and the first wiring 410, respectively. Each of the first hole and the first trench may be formed by an anisotropic etching process. In exemplary embodiments, the first trench in the second region II may have a structure substantially the same as or substantially similar to that of the trench described with reference to FIG. 6, FIG. 8 or FIG. 9.

A first contact 429 is formed in the first hole, and a first crack preventing structure 430 is formed in the first trench. The first contact 429 and the first crack preventing member 430 may be formed using metal and/or metal compound. For example, the first contact 429 and the first crack preventing structure 430 may include tungsten, titanium, aluminum, tantalum, copper, tungsten nitride, titanium nitride, aluminum nitride, tantalum nitride, tungsten silicide, titanium silicide, cobalt silicide, nickel silicide, etc. These may be used alone or in a mixture thereof. Each of the first contact 429 and the first crack preventing structure 430 may be formed by a sputtering process, a CVD process, an ALD process, a PLD process, an evaporation process, etc.

In formations of the first contact 429 and the first crack preventing member 430, a second conductive layer (not illustrated) may be formed on the first insulating interlayer 419 and the first insulation layer 420 to fill up the first hole and the first trench. The second conductive layer may be removed until the first insulating interlayer 419 and the first insulation layer 420 are exposed, so that the first contact 429 and the first crack preventing structure 430 are formed in the first insulating interlayer 419 and the first insulation layer 420, respectively. The second conductive layer may be partially removed by a CMP process and/or an etch-back process.

The first contact 429 makes contact with the first conductive wiring 409 in the first region I of the substrate 400. The first crack preventing structure 430 is electrically connected to the first wiring 410 in the second region II of the substrate 400. That is, the first crack preventing structure 430 is provided through the first insulation layer 410 in the second area II of the substrate 400.

A second insulating interlayer 434 is formed on the first insulating interlayer 419 and the first contact 429 in the first region I. Additionally, a second insulation layer 435 is formed on the first insulation layer 420 and the first crack preventing structure 430 in the second region II. Each of the second insulating interlayer 434 and the second insulation layer 435 may be formed using oxide, for example, silicon oxide. The second insulating interlayer 434 and the second insulation layer 435 may have flat upper surfaces by a CMP process and/or an etch-back process.

A second conductive wiring 439 is formed through the second insulating interlayer 434 and a second wiring 440 is formed in the second insulation layer 435. The second conductive wiring 439 and the second wiring 440 are respectively formed in a second hole and a first opening after partially etching the second insulating interlayer 434 and the second insulation layer 435 to form the second hole and the first opening. The second wiring 440 makes contact with the first crack preventing structure 430. Each of the second conductive wiring 439 and the second wiring 440 may be formed using metal and/or metal compound. For example, the second conductive wiring 439 and the second wiring 440 may include tungsten, titanium, aluminum, tantalum, copper, tungsten nitride, titanium nitride, aluminum nitride, tantalum nitride, tungsten silicide, titanium silicide, cobalt silicide, nickel silicide, etc. These may be used alone or in a mixture thereof.

In exemplary embodiments, the second wiring 440 may have a ring shape at an edge portion of the semiconductor device. That is, the first opening formed through the second insulation layer 435 may have a ring structure exposing the first crack preventing structure 430. Thus, the first crack preventing structure 430 may be interposed between the first wiring 410 and the second wiring 440.

A third insulating interlayer 444 is formed on the second insulating interlayer 434 and the second conductive wiring 439 in the first region I, and a third insulation layer 445 is formed on the second insulation layer 435 and the second wiring 440. The third insulating interlayer 444 and the third insulation layer 445 may be formed using oxide by a CVD process, a PECVD process, a spin coating process, an HDP-CVD process, etc. A planarization process may be performed about the third insulating interlayer 444 and the third insulation layer 445 to ensure level upper surfaces of the third insulating interlayer 444 and the third insulation layer 445.

In some exemplary embodiments, each of the third insulating interlayer 444 and the third insulation layer 445 may be formed using a low-k material having a dielectric constant below about 3.0. For example, each of the third insulating interlayer 444 and the third insulation layer 445 may include silicon oxide containing carbon (C).

The third insulating interlayer 444 and the third insulation layer 445 are partially etched to form a third hole (not illustrated) and a second trench (not illustrated). The second trench may partially expose the second wiring 440 buried in the second insulation layer 435.

A third conductive wiring 449 is formed in the third hole and a second crack preventing structure 450 is formed in the second trench. The second crack preventing structure 450 makes contact with the second wiring 440. Each of the third conductive wiring 449 and the second crack preventing structure 450 may be formed using metal and/or metal compound by a sputtering process, a CVD process, an ALD process, a PLD process, an evaporation process, etc. The third conductive wiring 449 and the second crack preventing structure 450 may be buried in the third insulating interlayer 444 and the third insulation layer 445, respectively.

A fourth insulating interlayer 451 is formed on the third insulating interlayer 444 and the third conductive wiring 449. Further, a fourth insulation layer 452 is formed on the second crack preventing structure 450 and the third insulation layer 435. The fourth insulating interlayer 451 and the fourth insulation layer 452 may be formed using oxide by a CVD process, a PECVD process, a spin coating process, an HDP-CVD process, etc. The fourth insulating interlayer 451 and the fourth insulation layer 452 may be planarized by a planarization process, such that the fourth insulating interlayer 451 and the fourth insulation layer 452 have flat upper surfaces, respectively.

A fourth conductive wiring 455 is formed in the fourth insulating interlayer 451 and a third wiring 460 is formed in the fourth insulation layer 452. The fourth conductive wiring 455 fills up a fourth hole (not illustrated) formed through the fourth insulating interlayer 451 by partially etching the fourth insulating interlayer 451. The third wiring 460 is formed in a second opening formed by partially etching the fourth insulation layer 452. The fourth hole and the second opening may be simultaneously formed. The third wiring 460 may be electrically connected to the second wiring 440 through the second crack preventing structure 450. Each of the fourth conductive wiring 455 and the third wiring 460 may be formed using metal and/or metal compound.

A fifth insulating interlayer 461 is formed on the fourth insulating interlayer 451 and the fourth conductive wiring 455. Additionally, a fifth insulation layer 462 is formed on the third wiring 460 and the fourth insulation layer 462. The fifth insulating interlayer 461 and the fifth insulation layer 462 may be formed using oxide by a CVD process, a PECVD process, a spin coating process, an HDP-CVD process, etc. In an exemplary embodiment, the fifth insulating interlayer 461 and the fifth insulation layer 462 may be planarized by a planarization process, so that the fifth insulating interlayer 461 and the fifth insulation layer 462 have level upper surfaces.

A fifth conductive wiring 465 is formed in the fifth insulating interlayer 461 and a third crack preventing structure 470 is formed in the fifth insulation layer 452. The fifth conductive wiring 465 is positioned in a fifth hole (not illustrated) formed through the fifth insulating interlayer 461 by partially etching the fifth insulating interlayer 461. The third crack preventing structure 470 is located in a third trench formed by partially etching the fifth insulation layer 462. The third crack preventing structure 470 may electrically make contact with to the third wiring 460. The fifth conductive wiring 465 and the third crack preventing structure 470 may be formed using metal and/or metal compound.

A sixth insulating interlayer 471 is formed on the fifth insulating interlayer 461 and the fifth conductive wiring 465. A sixth insulation layer 472 is formed on the third crack preventing structure 470 and the fifth insulation layer 462. The sixth insulating interlayer 471 and the sixth insulation layer 472 may be formed using oxide. The sixth insulating interlayer 471 and the sixth insulation layer 472 may have flat upper surfaces by planarizing upper portions of the sixth insulating interlayer 471 and the sixth insulation layer 472.

A sixth conductive wiring 475 is formed in the sixth insulating interlayer 471 and a fourth wiring 480 is formed in the sixth insulation layer 472. The sixth conductive wiring 475 is provided in a sixth hole formed through the sixth insulating interlayer 471 by partially etching the sixth insulating interlayer 471. The fourth wiring 480 is formed in a third opening formed through the sixth insulation layer 472 by partially etching the sixth insulation layer 472. The sixth hole and the third opening may be simultaneously formed. The fourth wiring 480 may be electrically connected to the third wiring 460 through the third crack preventing structure 470. The sixth conductive wiring 475 and the fourth wiring 480 may include metal and/or metal compound.

A seventh insulating interlayer 481 is formed on the sixth insulating interlayer 471 and the sixth conductive wiring 475. A seventh insulation layer 482 is formed on the third wiring 480 and the sixth insulation layer 472. Each of the seventh insulating interlayer 481 and the seventh insulation layer 482 may be formed using oxide. The seventh insulating interlayer 481 and the seventh insulation layer 482 may have level upper surfaces by planarizing upper portions of the seventh insulating interlayer 481 and the seventh insulation layer 482.

A seventh conductive wiring 485 is formed in the seventh insulating interlayer 481 and a fifth wiring 490 is formed on the fourth wiring 480. The seventh conductive wiring 485 is formed in a seventh hole formed through the seventh insulating interlayer 481. The fifth wiring 490 is formed in a fourth opening formed through the seventh insulation layer 482 by partially etching the seventh insulation layer 482. The seventh conductive wiring 485 and the fifth wiring 490 may include metal and/or metal compound.

A passivation layer 495 is formed on the seventh insulating interlayer 481 and the seventh insulation layer 482 to cover the seventh conductive wiring 485 and the fifth wiring 490. The passivation layer 495 may be formed using an organic material, oxide, nitride, etc.

The passivation layer 495 is partially etched to form an opening that partially exposes the seventh conductive wiring 485 to provide the pad of the semiconductor device. The opening of the passivation layer 495 may be formed by anisotropically etching the passivation layer 495.

In exemplary embodiments, a plurality of crack preventing structures may be obtained together with conductive wirings for a pad in a semiconductor device. Hence, additional processes may not be required for forming the crack preventing structures. When the semiconductor chip includes at least one crack preventing structure, the external impact may be absorbed and the stress may be dissipated as described above, so that lifting of insulation layers and/or generation of crack in the semiconductor chip may be effectively prevented. Therefore, the semiconductor chip may have improved reliability and durability, and also the semiconductor chip may ensure desired electrical connection.

FIG. 11 is a schematic plan view illustrating a semiconductor chip in accordance with exemplary embodiments.

Referring to FIG. 11, the semiconductor chip includes a substrate 500 having a cell area 510, a peripheral circuit area 520 and a pad area 530. A plurality of unit cells of a semiconductor device may be provided in the cell area 510, and circuit elements may be located in the peripheral circuit area 520. A plurality of pads 525 are positioned in the pad area 530. Predetermined signals may be applied to the semiconductor device through the pads 525.

The pad area 530 may be located at a peripheral portion of the semiconductor chip. When a semiconductor substrate is divided by the semiconductor chips, an external impact may be mainly applied to the pad area 530, and a stress may be generated in the pad area 530. Thus, the semiconductor chip further includes an additional area 540 adjacent to the pad area 530. At least one crack preventing structure (not illustrated) may be provided in the additional area 540. The crack preventing structure may have a construction substantially the same as or substantially similar to that of the crack preventing structure described with reference to FIG. 6, FIG. 8 or FIG. 9. Alternatively, the semiconductor chip may include a plurality of crack preventing structures substantially the same as or substantially similar to the crack preventing structures described with reference to FIG. 10.

In exemplary embodiments, the crack preventing structures may be formed while forming the pads of the semiconductor device. Thus, additional processes may not be required for forming the crack preventing structures.

When the semiconductor chip includes at least one crack preventing structure, the external impact may be absorbed and the stress may be dissipated as described above, so that lifting of insulation layers and/or generation of crack in the semiconductor chip may be effectively prevented. Therefore, the semiconductor chip may have improved reliability and durability and also the semiconductor chip may ensure desired electrical connection.

According to exemplary embodiments, a semiconductor device may include at least one crack preventing structure disposed adjacent to a pad, so that a degradation of the semiconductor chip caused by an external impact and/or a stress may be efficiently prevented by device crack preventing structure. Since the crack preventing structure having various constructions may be formed together with the pad of the semiconductor device, the crack preventing structure may be obtained simplified processes without additional processed for the crack preventing structure. The various crack preventing structures may be properly employed in various semiconductor devices, for example, DRAM devices, SRAM devices, flash memory devices, PRAM devices, etc.

The foregoing is illustrative of exemplary embodiments, and is not to be construed as limiting thereof. Although a few exemplary embodiments have been described, those skilled in the art will readily appreciate that many modifications are possible in the exemplary embodiments without materially departing from the novel teachings and advantages of exemplary embodiments. Accordingly, all such modifications are intended to be included within the scope of the inventive concept as defined in the claims. In the claims, means-plus-function clauses are intended to cover the structures described herein as performing the recited function and not only structural equivalents but also equivalent structures. Therefore, it is to be understood that the foregoing is illustrative of the inventive concept and is not to be construed as limited to the specific embodiments disclosed, and that modifications to the disclosed exemplary embodiments, as well as other exemplary embodiments, are intended to be included within the scope of the appended claims. The inventive concept is defined by the following claims, with equivalents of the claims to be included therein.

1. A semiconductor device comprising:
a wiring formed in a pad area of a substrate;
an insulation layer formed on the wiring; and
a crack preventing structure formed through the insulation layer,
wherein the crack preventing structure includes portions continuously extending in the insulation layer such that adjacent portions of the insulation layer are continuous with respect to each other.

2. The semiconductor device of claim 1, further comprising an etch stop layer formed between the wiring and the insulation layer, wherein the crack preventing structure passes through the etch stop layer to make contact with the wiring.

3. The semiconductor device of claim 1, wherein the crack preventing structure has a zigzag shape, a spiral shape or a helical matrix shape.

4. The semiconductor device of claim 1, wherein the crack preventing structure includes a conductive material substantially the same as that of the wiring.

5. The semiconductor device of claim 4, wherein the crack preventing structure includes metal and/or metal compound.

6. The semiconductor device of claim 1, wherein the wiring includes copper and the insulation layer includes silicon oxide or oxide containing carbon.

7. The semiconductor device of claim 1, wherein the insulation layer has a trench where the crack preventing structure is positioned.

8. A semiconductor device comprising:
unit cells formed in a cell area of a substrate;
circuit elements formed in a peripheral circuit area of the substrate;
a plurality of wirings formed in a pad area of the substrate;
a plurality of insulation layers formed on the plurality of wirings, respectively; and
a plurality of crack preventing structures between each wiring and each insulation layer,
wherein the crack preventing structures continuously extend in the insulation layers such that adjacent portions of the insulation layers are continuous.

9. The semiconductor device of claim 8, further comprising a pad formed adjacent to the crack preventing structures.

10. The semiconductor device of claim 9, wherein the pad includes a plurality of conductive wirings and a plurality of insulating interlayers interposed between adjacent conductive wirings.

11. The semiconductor device of claim 10, further comprising a passivation layer covering the pad and an upper most crack preventing structure wherein the passivation layer has an opening that partially exposes an upper most conductive wiring of the pad.

12. The semiconductor device of claim 8, wherein the semiconductor device comprises:
a first wiring formed on the pad area;
a first insulation layer formed on the first wiring;
a first crack preventing structure formed through the first insulation layer, the first crack preventing structure making contact with the first wiring;
a second wiring formed on the first crack preventing structure and the first insulation layer;
a second insulation layer formed on the second wiring;
a second crack preventing structure formed through the second insulation layer, the second crack preventing structure making contact with the second wiring;
a third wiring formed on the second crack preventing structure and the second insulation layer;
a third insulation layer formed on the third wiring; and
a third crack preventing structure formed through the third insulation layer, the third crack preventing structure making contact with the third wiring.

13. The semiconductor device of claim 12, wherein each of the first to the third crack preventing structures has a zigzag shape, a spiral shape or a helical matrix shape.

14-20. (canceled)
